(19) United States
(12) Patent Application Publication
(10) Pub. No.: US 2026/0066615 A1
(43) Pub. Date: Mar. 5, 2026

(54) LASER LIGHT SOURCE

(71) Applicant: NICHIA CORPORATION, Anan-shi (JP)

(72) Inventors: Seiji NAGAHARA, Tokushima-shi (JP); Makoto SHIMADA, Komatsushima-shi (JP)

(21) Appl. No.: 19/308,180

(22) Filed: Aug. 22, 2025

(30) Foreign Application Priority Data
Aug. 29, 2024 (JP) 2024-147938

(51) Int. Cl. H01S 5/024; H01S 5/00; H01S 5/02345; H01S 5/042; H01S 5/343

(52) U.S. Cl. CPC H01S 5/02469; H01S 5/04256; H01S 5/34326; H01S 5/0071; H01S 5/02345

(57) ABSTRACT

A laser light source includes a semiconductor structure, a first electrode, and a first metal portion. The semiconductor structure includes a semiconductor layer configured to emit light. The semiconductor structure has an upper surface. The first electrode is provided on the upper surface of the semiconductor structure. The first metal portion is provided on the first electrode, with the first electrode being partially exposed from the first metal portion. A pattern indicating information on the semiconductor structure is provided in a region where the first electrode is partially exposed.

### CROSS-REFERENCE TO RELATED APPLICATION

This application claims priority to Japanese Patent Application No. 2024-147938, filed on Aug. 29, 2024, the disclosure of which is hereby incorporated by reference in its entirety.

### TECHNICAL FIELD

The present disclosure relates to a laser light source.

### BACKGROUND

For example, in a laser light source having a semiconductor structure, the semiconductor structure is fabricated by singulating a large number of regions that have been provided in a matrix on a semiconductor wafer. To facilitate traceability of the semiconductor structure, a pattern indicating information on the semiconductor structure such as positional information on the semiconductor wafer may be formed on the semiconductor structure (See, for example, Japanese Patent Publication No. 2014-216448).

### SUMMARY

An object of the present disclosure is to suppress the occurrence of a pattern reading error in a laser light source having a pattern indicating information on a semiconductor structure.

A laser light source according to an embodiment of the present disclosure includes a semiconductor structure, a first electrode, and a first metal portion. The semiconductor structure includes a semiconductor layer configured to emit light. The semiconductor structure has an upper surface. The first electrode is provided on the upper surface of the semiconductor structure. The first metal portion is provided on the first electrode, with the first electrode being partially exposed from the first metal portion. A pattern indicating information on the semiconductor structure is provided in a region where the first electrode is partially exposed.

According to an embodiment of the present disclosure, in a laser light source having a pattern indicating information on a semiconductor structure, the occurrence of a pattern reading error can be suppressed.

### BRIEF DESCRIPTION OF DRAWINGS

FIG. 1 is a schematic top view illustrating a laser light source according to a first embodiment.

FIG. 2 is a schematic cross-sectional view taken along section line II-II in FIG. 1.

FIG. 3 is a schematic cross-sectional view taken along section line III-III in FIG. 1.

FIG. 4 is a schematic cross-sectional view (1) illustrating a laser light source according to a second embodiment.

FIG. 5 is a schematic cross-sectional view (2) illustrating a laser light source according to the second embodiment.

FIG. 6 is a schematic cross-sectional view (1) for explaining an example of a power supply method in a laser light source 2.

FIG. 7 is a schematic cross-sectional view (2) for explaining an example of a power supply method in the laser light source 2.

FIG. 8 is a schematic cross-sectional view (3) for explaining an example of a power supply method in the laser light source 2.

FIG. 9 is a schematic cross-sectional view (4) for explaining an example of a power supply method in the laser light source 2.

FIG. 10 is a schematic top view for explaining an example of a power supply method in a laser light source 3.

FIG. 11 is a schematic cross-sectional view taken along section line XI-XI in FIG. 10.

FIG. 12 is a schematic cross-sectional view taken along section line XII-XII in FIG. 10.

FIG. 13 is a schematic cross-sectional view for explaining an example of a package that accommodates a semiconductor structure 10.

### DETAILED DESCRIPTION

Hereinafter, embodiments for carrying out the invention are described with reference to the drawings. Note that, in the following description, terms indicating a specific direction or position (for example, “upper”, “lower”, and other terms related to those terms) are used, as necessary. However, these terms are used to facilitate understanding of the invention with reference to the drawings, and the technical scope of the present invention is not excessively limited by the meaning of these terms. For example, when the term “upper surface” is used, the invention does not always have to be used so as to face upward. Portions having the same reference characters appearing in a plurality of drawings indicate identical or equivalent portions or members. The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and is in contact with another member and a configuration in which a member covers another member with a space or an intervening member interposed therebetween.

The following embodiments exemplify a laser light source and the like for embodying a technical concept of the present invention, and the present invention is not limited to the description described below. The dimensions, materials, shapes, relative arrangements, and the like of constituent elements described below are not intended to limit the scope of the present invention to those alone but are intended to provide an example, unless otherwise specified. The contents described in an embodiment can be applied to any of the other embodiments and modified examples. The sizes, the positional relationship, and the like of the members illustrated in the drawings may be exaggerated to clarify the explanation. Furthermore, to avoid excessive complication of the drawings, a schematic view in which some elements are not illustrated may be used, or an end view illustrating only a cutting surface may be used as a cross-sectional view.

### First Embodiment

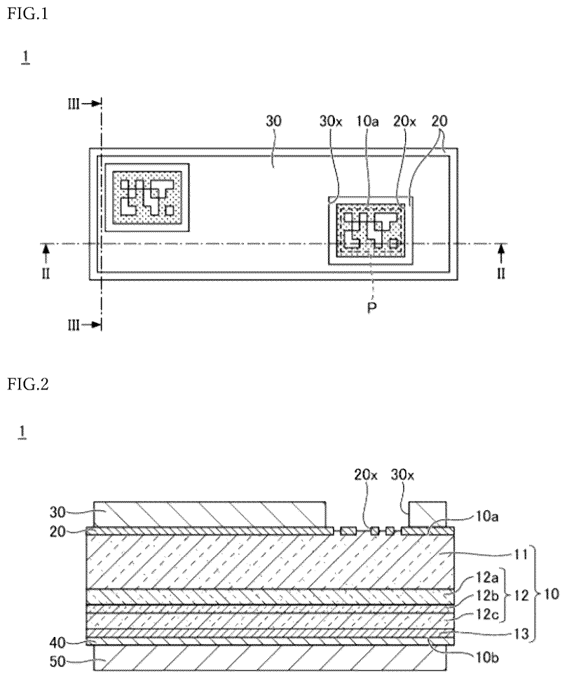

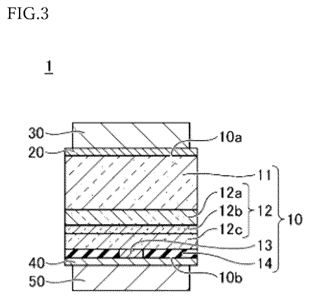

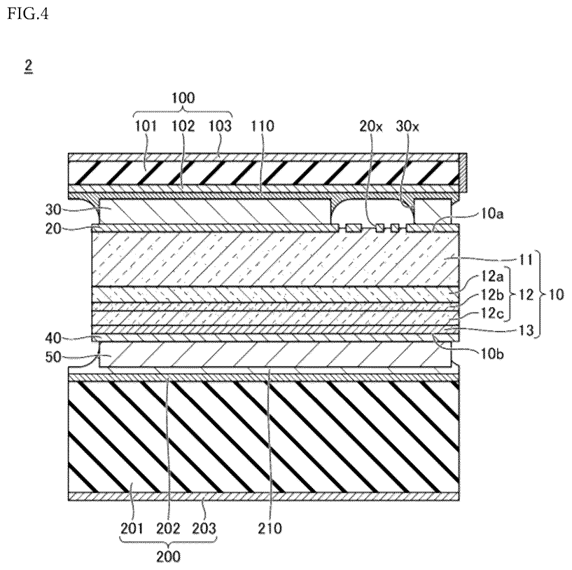

A laser light source 1 is described as an example of a laser light source according to the present disclosure. FIG. 1 is a schematic top view illustrating a laser light source according to a first embodiment. FIG. 2 is a schematic cross-sectional view taken along the section line II-II in FIG. 1. FIG. 3 is a schematic cross-sectional view taken along the section line III-III in FIG. 1.

As illustrated in FIGS. 1 to 3, the laser light source 1 includes, as a minimum configuration, a semiconductor structure 10 having an upper surface 10a and a lower surface 10b, a first electrode 20 provided on the upper surface 10a of the semiconductor structure 10, and a first metal portion 30 provided on the first electrode 20. The semiconductor structure 10 is a part of a semiconductor laser element and includes a substrate 11 and a semiconductor layer 12 that emits light.

In the examples illustrated in FIGS. 1 to 3, the laser light source 1 further includes a second electrode 40 and a second metal portion 50. The semiconductor structure 10 further includes a contact layer 13 and an insulating layer 14. The second electrode 40 is provided on the lower surface 10b of the semiconductor structure 10. The second electrode 40 is bonded to the semiconductor layer 12, for example, with interposition of the contact layer 13. In a top view, the area of the contact layer 13 is smaller than the areas of the semiconductor layer 12 and the second electrode 40. The insulating layer 14 surrounds the contact layer 13. The second metal portion 50 is provided on a side opposite to the semiconductor structure 10 with respect to the second electrode 40. That is, the second metal portion 50 is provided on a lower surface of the second electrode 40.

In the laser light source 1, an opening 30x is defined in the first metal portion 30. The first electrode 20 and the substrate 11 are partially exposed from the opening 30x of the first metal portion 30. A pattern P indicating information on the semiconductor structure 10 is provided in a region where the part of the first electrode 20 is exposed. More specifically, an opening 20x is defined in the first electrode 20. The opening 20x is formed in the opening 30x, that is, in the region where the first electrode 20 is partially exposed, and the substrate 11 of the semiconductor structure 10 is partially exposed from the opening 20x. The semiconductor structure 10 exposed from the opening 20x constitutes the pattern P. The pattern P can be formed by, for example, a photolithography method when the first electrode 20 is formed. With this configuration, the substrate 11 and the first electrode 20 can be used as the pattern P, and a separate member does not have to be prepared to provide the pattern P.

The pattern P is, for example, a data matrix. The pattern P indicates, for example, electrical characteristic data of the semiconductor structure 10, manufacturing conditions of the semiconductor structure 10, or positional information of the semiconductor structure 10 in a wafer. In a case in which the electrical characteristics are measured when the semiconductor structure 10 is manufactured, by providing the semiconductor structure 10 with the electrical characteristic data as the pattern P, the electrical characteristic data at the time of manufacturing the semiconductor structure 10 can be known after the manufacturing. In addition, by providing information on the manufacturing conditions at the time of manufacturing the semiconductor structure 10 to the semiconductor structure 10 as the pattern P, the manufacturing conditions of the semiconductor structure 10 can be known after the manufacturing. In addition, when the semiconductor structure 10 is manufactured by forming a plurality of semiconductor structures 10 on one wafer and then singulating the wafer into pieces, by providing the pattern P on each semiconductor structure 10 before the singulation, the position of the semiconductor structure 10 in the wafer after the singulation can be known after the singulation. Thus, traceability of the semiconductor structure 10 can be enhanced. In addition, the pattern P may be, for example, a two-dimensional code, a character, or a symbol other than the data matrix.

In addition, in the laser light source 1, the first metal portion 30 is provided on the first electrode 20, and the pattern P is disposed in the opening 30x of the first metal portion 30. Thus, the pattern P is less likely to come into contact with an object or the like outside the laser light source 1. This can reduce a possibility of damage to the pattern P or adhesion of a foreign substance to the pattern P. Therefore, a reading error of the pattern P can be made less likely to occur.

Each of the components of the laser light source 1 is described.

### Semiconductor Structure 10

The semiconductor structure 10 is an edge-emitting laser element. The upper surface 10a and the lower surface 10b of the semiconductor structure 10 are parallel to each other, for example. The semiconductor structure 10 has, for example, an outer shape of a rectangle in a top view. A lateral surface including one side of two short sides of the rectangle shape serves as a light emission surface of light emitted from the semiconductor structure 10. The upper surface 10a and the lower surface 10b of the semiconductor structure 10 have larger areas than the light emission surface.

In the semiconductor structure 10, the semiconductor layer 12 is provided below the substrate 11. The substrate 11 can be composed of, for example, an n-type semiconductor substrate. Examples of the n-type semiconductor substrate include a GaAs substrate, an InP substrate, and a GaP substrate. The substrate 11 is lattice-matched with the semiconductor layer 12. Thus, the crystallinity of the semiconductor layer 12 can be improved. Note that the substrate 11 preferably has a color that increases the contrast with the first electrode 20. For example, the color of the substrate 11 is a color based on black or gray, and the color of the first electrode 20 is a color based on white or yellow. For example, preferably, the substrate 11 has a lower reflectance (for example, from 20% to 50%) with respect to visible light including red light than the first electrode 20, and the first electrode 20 has a higher reflectance (for example, from 60% to 100%) with respect to visible light including red light than the substrate 11. Red light refers to, for example, light having a wavelength in a range from 600 nm to 780 nm. With this configuration, the boundary between the substrate 11 and the first electrode 20 becomes clear, and the pattern P is easily read.

The semiconductor layer 12 is provided on a lower surface of the substrate 11. The semiconductor layer 12 emits, for example, red light or infrared light. Red light or infrared light refers to, for example, light having a wavelength of 600 nm or more. In the illustrated example, the semiconductor layer 12 includes, for example, an n-type first cladding layer 12a, an active layer 12b, and a p-type second cladding layer 12c sequentially layered on the lower surface side of the substrate 11. Each of the first cladding layer 12a, the active layer 12b, and the second cladding layer 12c includes a semiconductor having a composition of a chemical formula of (Alₓ, Ga₁₋ₓ)_{y}In_{1-y}(P_{z},As_{1-z}) (0≤x, y, z≤1) in which composition ratios of x, y, and z are changed within respective ranges. The active layer 12b may have a single quantum well (SQW) structure, or may have a multi quantum well (MQW) structure including a plurality of well layers. The semiconductor layer 12 may have, for example, a resonator.

In the illustrated examples, the contact layer 13 is in contact with a part of a lower surface of the second cladding layer 12c. The contact layer 13 may not be in direct contact with the second cladding layer 12c, and another or other layers may be interposed therebetween. The contact layer 13 can be composed of, for example, GaAs, GaP, or the like. The insulating layer 14 surrounds a region of the lower surface of the second cladding layer 12c where the contact layer 13 is provided. The insulating layer 14 can be composed of, for example, SiO₂, ZrO₂, SiN, Al₂O₃, AlN, diamond, or the like. The insulating layer 14 may have a structure in which two or more of these materials are layered.

The semiconductor structure 10 can be fabricated by epitaxially growing each layer on the substrate 11 using, for example, an MOCVD apparatus.

### First Electrode 20

The first electrode 20 is provided on an upper surface of the substrate 11 constituting the semiconductor structure 10. As illustrated, the first electrode 20 may be partially embedded in the substrate 11. When the first electrode 20 is partially embedded in the substrate 11, the first electrode 20 can be provided by, for example, patterning the substrate 11 by a photolithography method, wet-etching the substrate 11 to remove a foreign substance on the surface of the substrate 11, and forming the first electrode 20.

The first electrode 20 may be provided so that a part of the first electrode 20 is not embedded in the substrate 11 and the lower surface thereof is in contact with the upper surface of the substrate 11. In other words, in the upper surface of the substrate 11, a portion that is in contact with the first electrode 20 and a portion that is not in contact with the first electrode 20 may have the same height. The first electrode 20 functions as, for example, an N-side electrode. The first electrode 20 can be composed of, for example, AuGe, Ni, Ti, Mo, W, Pd, Pt, Au, or the like. The first electrode 20 may have a structure in which two or more of these materials are layered. The first electrode 20 can be provided on the upper surface of the substrate 11 by, for example, a sputtering method.

### First Metal Portion 30

The first metal portion 30 can be partially provided on an upper surface of the first electrode 20. For example, in a top view, the outer peripheral portion of the upper surface of the first electrode 20 may be exposed from the first metal portion 30. The first metal portion 30 may be provided on the entire upper surface of the first electrode 20. The first metal portion 30 functions as, for example, a pad connected to a metal wiring for supplying power to the laser light source 1. In another example, the first metal portion 30 is bonded to, for example, a first heat dissipation member 100. The first metal portion 30 can be composed of, for example, Au. The first metal portion 30 can be provided on the upper surface of the first electrode 20 by, for example, a plating method or a sputtering method. The first metal portion 30 is preferably thicker than the first electrode 20. This can reduce the possibility that the pattern P comes into contact with an external object or the like. From the viewpoint of making it difficult for the pattern P to come into contact with an object or the like outside the laser light source 1, the thickness of the first metal portion 30 is preferably 1 μm or more. The opening 30x defined in the first metal portion 30 has, for example, a rectangular shape in a top view. Note that the rectangular shape includes a square shape. The length of a short side and a long side of the opening 30x may be, for example, in a range from 100 μm to 200 μm.

### Second Electrode 40

The second electrode 40 functions as a P-side electrode. The second electrode 40 can be composed of, for example, Ni, Ti, Mo, W, Pd, Pt, Au, ITO, or the like. The second electrode 40 may have a structure in which two or more of these materials are layered. The second electrode 40 can be provided, for example, on lower surfaces of the contact layer 13 and the insulating layer 14 by a sputtering method. The second electrode 40 is bonded to the second cladding layer 12c constituting the semiconductor layer 12 with interposition of the contact layer 13, for example. With this configuration, power can be appropriately supplied to the semiconductor structure 10.

### Second Metal Portion 50

The second metal portion 50 can be provided on a part of the lower surface of the second electrode 40. For example, the outer peripheral portion of the lower surface of the second electrode 40 may be exposed from the second metal portion 50 in bottom view. The second metal portion 50 may be provided on the entire lower surface of the second electrode 40. The second metal portion 50 functions as, for example, a pad connected to a metal wiring for supplying power to the laser light source 1. In another example, the second metal portion 50 is bonded to, for example, a second heat dissipation member 200. The second metal portion 50 can be composed of, for example, Au. The second metal portion 50 can be provided on the lower surface of the second electrode 40 by, for example, a plating method or a sputtering method. The second metal portion 50 is preferably thicker than the second electrode 40. The thickness of the second metal portion 50 can be, for example, the same as the thickness of the first metal portion 30. The same thickness includes a case in which a difference in thickness is 0.5 μm or less. By providing the second metal portion 50, the upper side of the semiconductor structure 10 where the first metal portion 30 is provided and the lower side of the semiconductor structure 10 are symmetrical to each other, the warpage of the substrate due to the second metal portion 50 and the warpage of the substrate due to the first metal portion 30 are equal to each other, so that the warpage of the semiconductor structure 10 can be reduced.

### Second Embodiment

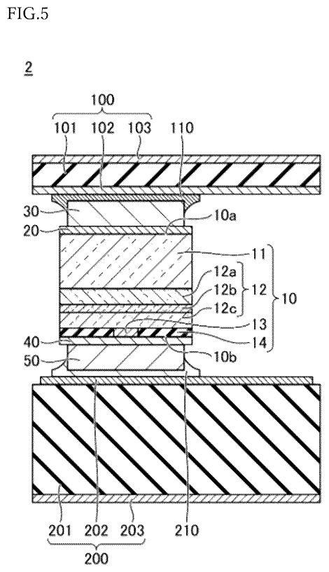

As another example of the laser light source according to the present disclosure, a laser light source 2 is described. FIG. 4 is a schematic cross-sectional view (1) illustrating a laser light source according to the second embodiment, and illustrates a cross section corresponding to FIG. 2. FIG. 5 is a schematic cross-sectional view (2) illustrating a laser light source according to the second embodiment, and illustrates a cross section corresponding to FIG. 3.

As illustrated in FIGS. 4 and 5, the laser light source 2 is different from the laser light source 1 in that the laser light source 2 includes a first heat dissipation member 100 and a second heat dissipation member 200.

In a top view, the first heat dissipation member 100 is provided on the first metal portion 30 to cover the pattern P illustrated in FIG. 1. The first heat dissipation member 100 covers the pattern P, so that the efficiency of heat dissipation by the first heat dissipation member 100 is improved. The first heat dissipation member 100 is, for example, a rectangular parallelepiped. In the illustrated example, the entire first metal portion 30 overlaps the first heat dissipation member 100 in a top view. With this configuration, the efficiency of heat dissipation of the first metal portion 30 by the first heat dissipation member 100 is improved. The first heat dissipation member 100 includes a first intermediate layer 101 and a first metal film 102 provided on a lower surface of the first intermediate layer 101. In the illustrated example, the first heat dissipation member 100 includes a second metal film 103 provided on an upper surface of the first intermediate layer 101. In the illustrated example, the first metal film 102 is electrically connected to the second metal film 103 via a metal film located on a lateral surface of the first intermediate layer 101. The first metal film 102 located on the lower surface of the first intermediate layer 101 is bonded to the first metal portion 30 with interposition of a first bonding member 110 having conductivity. With this configuration, the first heat dissipation member 100 and the first metal portion 30 are firmly fixed to each other. In the illustrated example, the first bonding member 110 forms a fillet along an outer surface of the first metal portion 30 and an inner surface of the first metal portion 30 that defines the opening 30x. The first bonding member 110 is not in contact with the pattern P.

The second heat dissipation member 200 is provided on a side of the second metal portion 50 opposite to the second electrode 40. By providing the second heat dissipation member 200, the upper side of the semiconductor structure 10 on which the first heat dissipation member 100 is provided and the lower side of the semiconductor structure 10 are symmetrical to each other, and the warpage of the substrate due to the second heat dissipation member 200 and the warpage of the substrate due to the first heat dissipation member 100 are equal to each other, so that the warpage of the semiconductor structure 10 can be reduced. The second heat dissipation member 200 is, for example, a rectangular parallelepiped. The thickness of the second heat dissipation member 200 may or may not have to be the same as that of the first heat dissipation member 100. In the illustrated example, the entire second metal portion 50 overlaps the second heat dissipation member 200 in a top view. With this configuration, the efficiency of heat dissipation of the second metal portion 50 by the second heat dissipation member 200 is improved. The second heat dissipation member 200 includes a second intermediate layer 201 and a third metal film 202 provided on an upper surface of the second intermediate layer 201. In the illustrated example, the second heat dissipation member 200 further includes a fourth metal film 203 provided on a lower surface of the second intermediate layer 201. The third metal film 202 is bonded to the second metal portion 50 with interposition of a second bonding member 210 having conductivity. With this configuration, the third metal film 202 and the second metal portion 50 are firmly fixed to each other. In the illustrated example, the second bonding member 210 forms a fillet along the lateral surface of the second metal portion 50. The semiconductor structure 10 may protrude from the second heat dissipation member 200. This structure can reduce the possibility that light emitted from the semiconductor structure 10 is blocked by the second heat dissipation member 200.

The first intermediate layer 101 can be composed of, for example, AlN, SiC, Al₂O₃, SiN, graphite, diamond, or the like, and is preferably composed of AlN, SiC, graphite, diamond, or the like. Thus, the heat dissipation property of the first intermediate layer 101 can be improved. The first intermediate layer 101 may have a structure in which two or more of these materials are layered. The first intermediate layer 101 may be composed of a metal such as Cu. The same applies to the second intermediate layer 201. The first metal film 102 can be composed of, for example, AuSn, Au, Ag, Cu, solder, a metal nanomaterial, or the like. The first metal film 102 may have a structure in which two or more of these materials are layered. The same applies to the third metal film 202 and the fourth metal film 203. The first bonding member 110 can be composed of, for example, AuSn, solder, a metal nanomaterial, or the like. The same applies to the second bonding member 210.

The thermal conductivity of the first heat dissipation member 100 and the second heat dissipation member 200 may be, for example, in a range from 10 [W/m·K] to 2500 [W/m·K], and is preferably in a range from 100 [W/m K] to 2500 [W/m·K]. With such thermal conductivity, the first heat dissipation member 100 and the second heat dissipation member 200 can efficiently transfer, to the outside, heat generated from the semiconductor structure 10 when the laser light source 1 emits light. In particular, in the case of the semiconductor structure 10 in which the semiconductor layer 12 emits red light or infrared light, the characteristics such as optical output vary greatly with temperature. Therefore, improving heat dissipation is effective by providing the first heat dissipation member 100 and the second heat dissipation member 200 to dissipate heat from both the upper portion and the lower portion of the semiconductor structure 10. Note that the laser light source 2 may include only one of the first heat dissipation member 100 and the second heat dissipation member 200.

In the laser light source 2, because the first heat dissipation member 100 is provided on the first metal portion 30 to cover the pattern P in a top view, the pattern P is not readable as it is. For example, when the pattern P is to be read to analyze information of the laser light source 2, the first bonding member 110 and the first heat dissipation member 100 need to be peeled off.

For example, in a case in which the first metal portion 30 is not provided in a general laser light source, when the first heat dissipation member 100 is provided directly on the first electrode 20 with interposition of the first bonding member 110, the first bonding member 110 may come into contact with the pattern P and fill the pattern P. In a case in which the first bonding member 110 is in contact with the pattern P, completely removing the first bonding member 110 in contact with the pattern P is difficult when the first bonding member 110 and the first heat dissipation member 100 are peeled off. Therefore, the first bonding member 110 partially remains on the pattern P, and a reading error of the pattern P is likely to occur when the pattern P is read.

On the other hand, in the laser light source 2, the first metal portion 30 is provided on the first electrode 20, and the first heat dissipation member 100 is provided on the first metal portion 30 with interposition of the first bonding member 110. Therefore, the first bonding member 110 can easily be made not to come into contact with the pattern P by adjusting the thickness of the first metal portion 30 and/or the amount of the first bonding member 110. Because the first bonding member 110 is not in contact with the pattern P, when the first bonding member 110 and the first heat dissipation member 100 are peeled off, the pattern P to which the residue of the first bonding member 110 is not attached is exposed in the opening 30x of the first metal portion 30. As a result, when the pattern P is read, a reading error of the pattern P can be made less likely to occur.

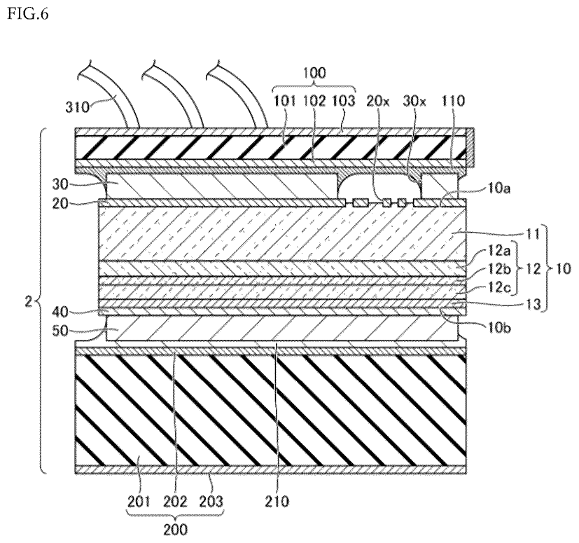

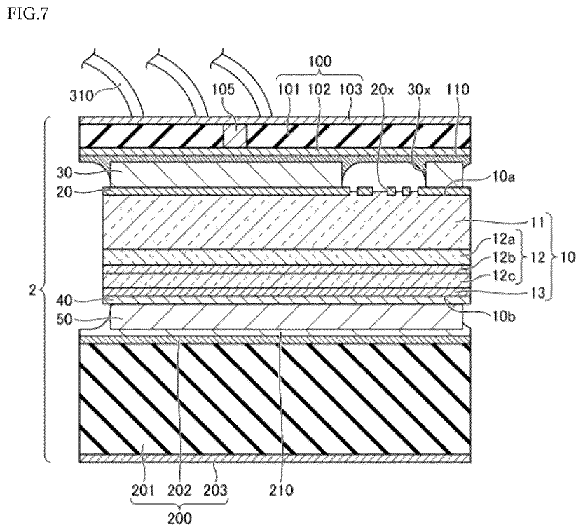

An example of a power supply method in the laser light source 2 is described below. In the laser light source 2, the first heat dissipation member 100 includes the second metal film 103 provided on the upper surface of the first intermediate layer 101, and the second metal film 103 is electrically connected to the first metal film 102. With this configuration, the first heat dissipation member 100 can also be used as a power supply member to the semiconductor structure 10. A specific power supply method is described below. FIG. 6 is a schematic cross-sectional view (1) for explaining an example of a power supply method in the laser light source 2, and illustrates a cross section corresponding to FIG. 4. FIG. 6 illustrates a power supply method to the first electrode 20. In the example illustrated in FIG. 6, a metal wire 310 is bonded to the second metal film 103 located on the upper surface of the first intermediate layer 101 in the first heat dissipation member 100. The metal wire 310 is, for example, a gold wire, a copper wire, or the like, and can be bonded to the second metal film 103 by a wire bonding method. Power can be supplied from the metal wire 310 to the first electrode 20 via the second metal film 103 located on the upper surface of the first intermediate layer 101, the metal film located on the lateral surface of the first intermediate layer 101, the first metal film 102 located on the lower surface of the first intermediate layer 101, the first bonding member 110 having conductivity, and the first metal portion 30 in this order. With such a configuration, because the surface of the first heat dissipation member 100 can be used as a power supply path to the semiconductor structure 10, any other power supply path needs not be provided inside the first intermediate layer 101.

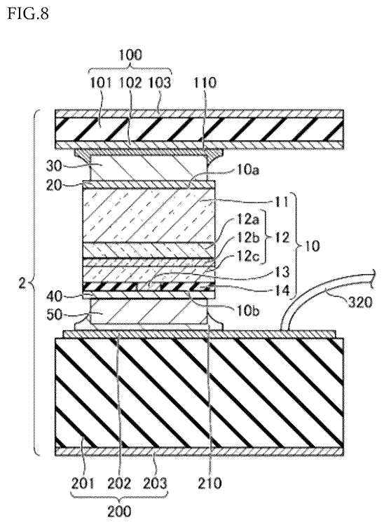

FIG. 7 is a schematic cross-sectional view (2) for explaining an example of a power supply method in the laser light source 2, and illustrates a cross section corresponding to FIG. 4. In the example of FIG. 6, the first metal film 102 is connected to the second metal film 103 via the metal film located from the lower surface to the lateral surface of the first intermediate layer 101; however, the configuration illustrated in FIG. 7 may be used instead. In the example of FIG. 7, the first metal film 102 is provided on the lower surface of the first intermediate layer 101, and the second metal film 103 is provided on the upper surface of the first intermediate layer 101. The first metal film 102 and the second metal film 103 are electrically connected to each other with interposition of a via electrode 105 passing through the first intermediate layer 101. The metal wire 310 is bonded to the second metal film 103. Note that no metal film is provided on the lateral surface of the first intermediate layer 101. In the example of FIG. 7, power can be supplied from the metal wire 310 to the first electrode 20 via the second metal film 103, the via electrode 105, the first metal film 102, the first bonding member 110 having conductivity, and the first metal portion 30 in this order. With such a configuration, a power supply path from the second metal film 103 to the first metal film 102 can be protected by the first intermediate layer 101.

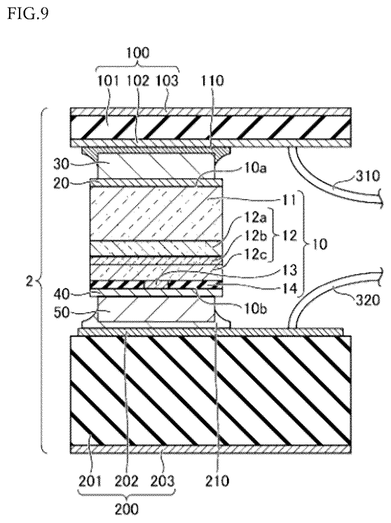

FIG. 8 is a schematic cross-sectional view (3) for explaining an example of a power supply method in the laser light source 2, and illustrates a cross section corresponding to FIG. 5. FIG. 8 illustrates a power supply method to the second electrode 40. In the example illustrated in FIG. 8, a metal wire 320 is bonded to the third metal film 202 located on the upper surface of the second intermediate layer 201 in the second heat dissipation member 200. The metal wire 320 is, for example, a gold wire, a copper wire, or the like, and can be bonded to the third metal film 202 by a wire bonding method. Power can be supplied from the metal wire 320 to the second electrode 40 via the third metal film 202, the second bonding member 210 having conductivity, and the second metal portion 50 in this order.

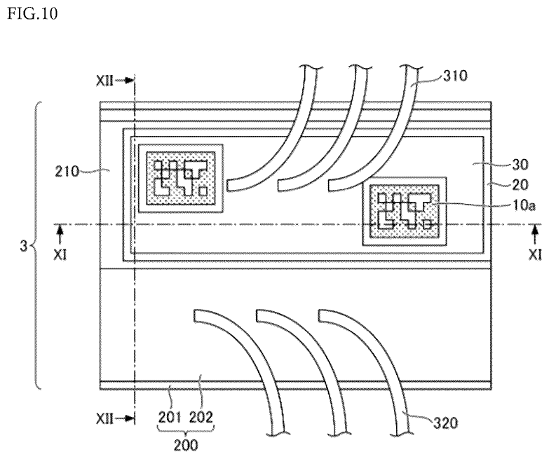

FIG. 9 is a schematic cross-sectional view (4) illustrating the laser light source according to the second embodiment, and illustrates a cross section corresponding to FIG. 5. FIG. 9 illustrates a power supply method to the first electrode 20 and the second electrode 40. The power supply method to the first electrode 20 may use a configuration illustrated in FIG. 9 instead of the configurations illustrated in FIGS. 6 and 7. In the example illustrated in FIG. 9, the metal wire 310 is bonded to the first metal film 102 located on the lower surface of the first intermediate layer 101 in the first heat dissipation member 100. Power can be supplied from the metal wire 310 to the first electrode 20 via the first metal film 102, the first bonding member 110 having conductivity, and the first metal portion 30 in this order. In FIG. 9, the power supply method to the second electrode 40 is substantially the same as that in FIG. 8.

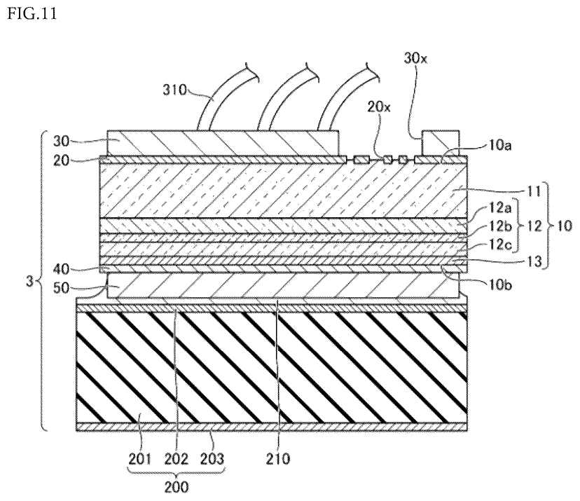

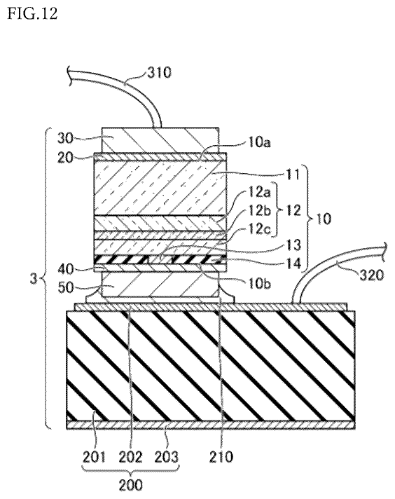

FIG. 10 is a schematic top view for explaining an example of a power supply method in a laser light source 3. FIG. 11 is a schematic cross-sectional view taken along the section line XI-XI in FIG. 10. FIG. 12 is a schematic cross-sectional view taken along the section line XII-XII in FIG. 10.

As illustrated in FIGS. 10 to 12, the laser light source 3 is different from the laser light source 2 in that the laser light source 3 includes no first heat dissipation member 100. In the example illustrated in FIGS. 10 to 12, because the first metal portion 30 is exposed on the outermost surface, the metal wire 310 is bonded to the first metal portion 30. Power can be supplied from the metal wire 310 to the first electrode 20 via the first metal portion 30. In FIGS. 10 to 12, a power supply method to the second electrode 40 is substantially the same as that in FIG. 8.

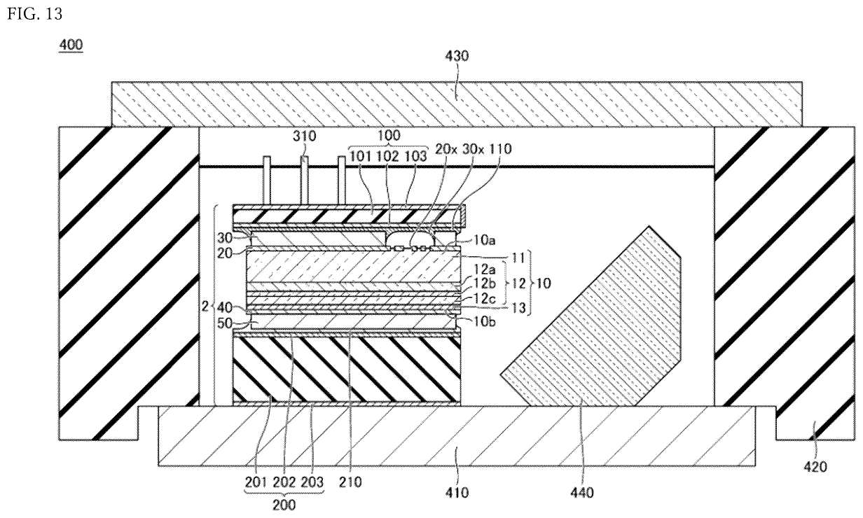

FIG. 13 is a schematic cross-sectional view for explaining an example of a package disposed with the semiconductor structure 10. As illustrated in FIG. 13, a package 400 includes a base portion 410 and a frame portion 420. The package 400 is provided with a reflective member 440 and a light-transmissive member 430. The reflective member 440 reflects light emitted from the semiconductor structure 10 upward. The light-transmissive member 430 transmits the light reflected by the reflective member 440. Because the semiconductor structure 10 is disposed inside the package 400, the semiconductor structure 10 can be protected from contamination. The package 400 may be further provided with a member such as a lens.

Although the preferred embodiments and the like have been described in detail above, the invention is not limited to the above-described embodiments and the like, various modifications and substitutions can be made to the above-described embodiments and the like without departing from the scope described in the claims.

What is claimed is:

1. A laser light source comprising:
a semiconductor structure including a semiconductor layer configured to emit light, the semiconductor structure having an upper surface;
a first electrode on the upper surface of the semiconductor structure; and
a first metal portion provided on the first electrode, with the first electrode being partially exposed from the first metal portion, wherein
a pattern indicating information on the semiconductor structure is provided in a region where the first electrode is partially exposed.

2. The laser light source according to claim 1, wherein
the first electrode defines an opening in the region where the first electrode is partially exposed,
the semiconductor structure is partially exposed from the opening, and
a part of the semiconductor structure exposed from the opening constitutes the pattern.

3. The laser light source according to claim 1, further comprising
a first heat dissipation member on the first metal portion to cover the pattern in a top view.

4. The laser light source according to claim 3, wherein
the first heat dissipation member includes,
a first intermediate layer, and
a first metal film on a lower surface of the first intermediate layer, and
the first metal film is bonded to the first metal portion with interposition of a first bonding member having conductivity.

5. The laser light source according to claim 4, wherein
the first heat dissipation member includes a second metal film on an upper surface of the first intermediate layer, and
the second metal film is electrically connected to the first metal film.

6. The laser light source according to claim 1, further comprising:
a second electrode on a lower surface of the semiconductor structure;
a second metal portion on a side of the second electrode opposite to the semiconductor structure; and
a second heat dissipation member on a side of the second metal portion opposite to the second electrode.

7. The laser light source according to claim 6, wherein
the semiconductor structure includes a substrate,
the first electrode is provided on an upper surface of the substrate,
the semiconductor layer is provided on a lower surface of the substrate,
the semiconductor layer includes a first cladding layer, an active layer, and a second cladding layer sequentially layered on a side of the lower surface of the substrate, and
the second electrode is bonded to the second cladding layer with interposition of a contact layer.

8. The laser light source according to claim 7, wherein
the semiconductor layer is configured to emit red laser light or infrared laser light,
the substrate is lattice-matched with the semiconductor layer, and
the substrate is partially exposed from the first metal portion.

9. The laser light source according to claim 6, wherein
the second heat dissipation member includes
a second intermediate layer, and
a third metal film on an upper surface of the second intermediate layer, and
the third metal film is bonded to the second metal portion with interposition of a second bonding member having conductivity.

10. The laser light source according to claim 4, wherein
the first bonding member is not in contact with the pattern.
